(19) United States
(12) Patent Application Publication
(10) Pub. No.: US 2024/0333288 A1
(43) Pub. Date: Oct. 3, 2024

(54) KEY DETECTION METHOD AND SYSTEM

(71) Applicant: GOERTEK INC., Weifang, Shandong (CN)

(72) Inventor: Lei CHEN, Weifang, Shandong (CN)

(21) Appl. No.: 18/291,259

(22) PCT Filed: Jul. 21, 2022
(86) PCT No.: PCT/CN2022/107102

§ 371 Date: Jan. 23, 2024

(30) Foreign Application Priority Data
Aug. 2, 2021 (CN) 202110882825.0

(51) Int. Cl. H03K 17/96

(52) U.S. Cl. CPC H03K 17/96

(57) ABSTRACT

The present disclosure provides a key detection method and system, the method comprises: collecting voltage values of a key during a period from pressing to releasing according to a predetermined frequency, to obtain a voltage data set corresponding to the key; performing a curve fitting on the voltage values in the voltage data set and time to obtain a first fitting curve; obtaining a time set in which a derivative of the first fitting curve is zero, and comparing the time set with a first predetermined set to obtain a first comparison result; obtaining a positive and negative derivative set of each element in the time set within a predetermined range based on the first comparison result, and comparing it with a second predetermined set to obtain a second comparison result; determining current state information of the key based on the first comparison result and the second comparison result.

The present application claims priority to Chinese patent application No. 202110882825.0, filed with the Chinese Patent Office on Aug. 2, 2021, entitled “Key Detection Method and System”, the entire contents of which are incorporated herein by reference.

### TECHNICAL FIELD

The present disclosure relates to the field of key-pressing technology, and more specifically, to a key detection method and system.

### DESCRIPTION OF RELATED ART

Traditional mechanical keys have limited service life and poor control experience, which makes other types of alternative keys such as touch keys or piezoelectric effect keys continue to be developed and applied, such type of keys realize conduction or transmission of corresponding signal by pressing the keys during the using process, which can easily be mistakenly pressed after long term of usage, so that the key's accuracy cannot be guaranteed, affecting the user experience.

### SUMMARY

In view of the above problems, a purpose of the present disclosure is to provide a key detection method and system to solve the problems such as low accuracy and poor user experience of the existing keys.

The key detection method provided by the present disclosure comprises: collecting voltage values of a key to be detected during a period from pressing to releasing according to a predetermined frequency, to obtain a voltage data set corresponding to the key to be detected; performing a curve fitting on the voltage values in the voltage data set and time to obtain a first fitting curve; obtaining a time set in which derivative of the first fitting curve is zero, and comparing the time set with a first predetermined set to obtain a first comparison result, wherein the first predetermined set comprises a sample time set corresponding to the sample key; obtaining a positive and negative derivative set of each element in the time set within a predetermined range based on the first comparison result, and comparing the positive and negative derivative set with the second predetermined set to obtain a second comparison result, wherein the second predetermined set comprises a positive and negative derivative set corresponding to the sample time set; and determining current state information of the key to be detected, based on the first comparison result and the second comparison result.

In addition, an optional technical solution is that a process of obtaining the first predetermined set comprises: obtaining voltage values of the sample key during a period from normal pressing to releasing to obtain a sample voltage data set corresponding to the sample key; performing a curve fitting on the voltage values in the sample voltage data set and time to obtain a second fitting curve; and obtaining a sample time set in which a derivative of the second fitting curve is zero to form the first predetermined set.

In addition, an optional technical solution is that a process of obtaining the second predetermined set comprises: obtaining a positive and negative derivative set of each element in the first predetermined set within a predetermined range to form the second predetermined set, wherein the predetermined range comprises any one of time points at left and right sides of each element in the first predetermined set, and the second predetermined set comprises a derivative of the second fitting curve corresponding to the any one of the time points at the left and right sides of each element in the first predetermined set.

In addition, an optional technical solution is that the process of obtaining a first comparison result comprises: determining whether the number of elements in the time set is the same as the number of elements in the first predetermined set, and if the number of elements in the time set is the same as the number of elements in the first predetermined set, further obtaining a positive and negative derivative set of each element in the time set within a predetermined range and comparing the positive and negative derivative set with the first predetermined set; if the number of elements in the time set is different from the number of elements in the first predetermined set, determining that the key to be detected is in a non-pressed state, and continuing to collect voltage values of the key to be detected and iteratively updating and storing the voltage values into the voltage data set.

In addition, an optional technical solution is that the process of obtaining a second comparison result comprises: determining whether the number of positive and negative elements are the same between the positive and negative derivative set and the second predetermined set; if the number of positive and negative elements are the same between the positive and negative derivative set and the second predetermined set, determining that the key to be detected is in a normal pressed state; and if the number of positive elements or the number of negative elements is different between the positive and negative derivative set and the second predetermined set, determining that the key to be detected is in a non-pressed state, and continuing to collect voltage values of the key to be detected and iteratively updating and storing the voltage values into the voltage data set.

In addition, an optional technical solution is that the process of collecting voltage values of the key to be detected and iteratively updating and storing the voltage values into the voltage data set comprises: adding collected current voltage values of the key to be detected to the voltage data set, and removing a voltage value collected at the earliest time in the voltage data set when the number of the voltage values in the voltage data set exceeds a predetermined threshold value.

In addition, an optional technical solution is that the process of performing a curve fitting on voltage values in the voltage data set and time comprises: performing a curve fitting on the voltage values in the voltage data set and time by using a least squares method.

Furthermore, an optional technical solution is that the number of elements in the second predetermined set is greater than the number of elements in the first predetermined set.

Furthermore, an optional technical solution is that the key comprises a piezoelectric ceramic key.

According to another aspect of the present disclosure, a key detection system, comprising: a voltage data set obtaining unit for collecting voltage values of a key to be detected during a period from pressing to releasing according to a predetermined frequency, to obtain a voltage data set corresponding to the key to be detected; a first fitting curve obtaining unit for performing a curve fitting on the voltage values in the voltage data set and time to obtain a first fitting curve; a first comparison result obtaining unit for obtaining a time set in which a derivative of the first fitting curve is zero, and comparing the time set with a first predetermined set to obtain a first comparison result, wherein the first predetermined set comprises a sample time set corresponding to a sample key; a second comparison result obtaining unit for obtaining a positive and negative derivative set of each element in the time set within a predetermined range based on the first comparison result, and comparing the positive and negative derivative set with a second predetermined set to obtain a second comparison result, wherein the second predetermined set comprises a positive and negative derivative set corresponding to the sample time set; and a state information determination unit for determining current state information of the key to be detected based on the first comparison result and the second comparison result.

By using the above key detection method and system, it is possible to determine the current state information of the key to be detected based on the above first comparison result and the second comparison result, realizing accurate determination of the state of the key, avoiding signal error transmission caused by error operation or passive pressing, and providing high key detection accuracy and a strong sense of user experience.

In order to realize the above and related purposes, one or more aspects of the present disclosure include features that will be described in detail in the followings. The following description, as well as the accompanying drawings, illustrate certain exemplary aspects of the present disclosure in detail. However, these aspects are examples of only some of the various ways in which the principles of the present disclosure may be used. Moreover, the present disclosure is intended to include all of these aspects as well as their equivalents.

### BRIEF DESCRIPTION OF DRAWINGS

By referring to the following description together with the accompanying drawings, and as the present disclosure is more fully understood, other objects and results of the present disclosure will be better understood and easily comprehended by referring to the following description together with the accompanying drawings. In the accompanying drawings:

FIG. 1 is a flow diagram of a key detection method according to an embodiment of the present disclosure; and

FIG. 2 is a logic block diagram of a key detection system according to an embodiment of the present disclosure.

The same reference signs indicate similar or corresponding features or functions in all the drawings.

### DETAILED DESCRIPTIONS

In order to make the purpose, technical solutions and advantages of the embodiments of the present disclosure clearer, the technical solutions in the embodiments of the present disclosure will be described clearly and completely in the following in conjunction with the accompanying drawings in the embodiments of the present disclosure, and it is obvious that the described embodiments are a part of the embodiments of the present disclosure and not all of the embodiments. Based on the embodiments in the present disclosure, all other embodiments obtained by a person of ordinary skill in the art without making creative labor fall within the scope of protection of the present disclosure.

In the following description, many specific details are set forth for illustrative purposes in order to provide a full understanding of one or more embodiments. However, it is clear that it is also possible to realize these embodiments without these specific details. In other examples, for ease of describing one or more embodiments, well-known structures and devices are shown in the form of block diagrams.

In the description of the present disclosure, it is to be understood that the terms “center”, “longitudinal”, “transverse”, “length”, “width”, “thickness”, “top”, “bottom”, “front”, “back”, “left”, “right”, “vertical”, “horizontal”, “top”, “bottom”, “inside”, “outer”, “clockwise”, “counterclockwise”, “axial”, “radial”, “circumferential”, etc. indicate orientation or positional relationships based on those shown in the accompanying drawings, and are intended only to facilitate the description of the present disclosure and to simplify the description, and are not intended to indicate or imply that the device or element referred to must have a particular orientation, be constructed and operated in a particular orientation, and therefore cannot be construed as a limitation of the present disclosure.

For the purpose of describing the key detection method and system of the present disclosure in detail, specific embodiments of the present disclosure will be described in detail below in conjunction with the accompanying drawings.

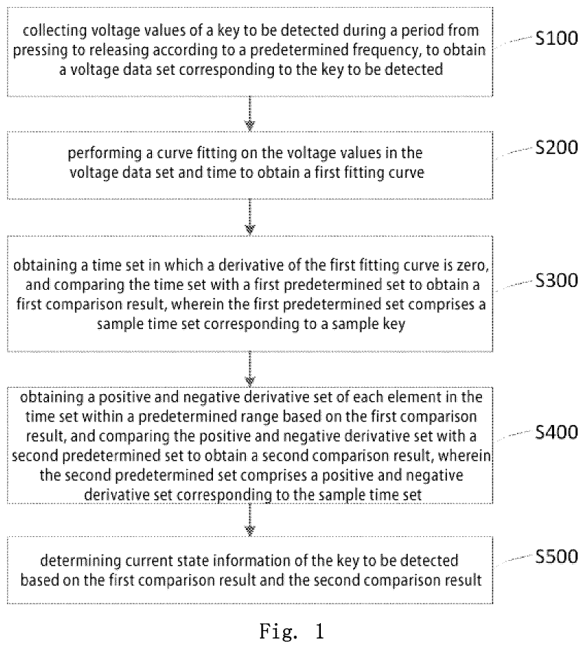

FIG. 1 illustrates a schematic flow diagram of a key detection method according to an embodiment of the present disclosure.

As shown in FIG. 1, the key detection method of the embodiment of the present disclosure comprises:

S100: collecting voltage values of the key to be detected during a period from pressing to releasing according to a predetermined frequency, to obtain a voltage data set corresponding to the key to be detected.

Wherein, the voltage value of the key to be detected (hereinafter referred to as the key) may be collected by setting a certain collecting frequency (the voltage value may be adopted as a voltage difference between the voltages at the two ends of the key to be detected), obtaining voltage value information at each of times, and combining all the voltage value information to form a voltage data set corresponding to the key to be detected, so as to perform a fitting on the voltage values in the voltage data set and time subsequently.

As a specific example, assuming that the sampling frequency for reading the voltage value is mHz, and the period from pressing to releasing the key to be detected is T, the obtained voltage data set can be expressed as C (V₁, T₁), V₁ represents the voltage value read at the timing T₁, and the number of data in the voltage data set is m*T.

S200: Performing a curve fitting on the voltage values in the voltage data set and time, to obtain a first fitting curve.

Wherein the curve fitting of multiple groups of voltage values in the voltage data set and time data may be performed by using the least squares method, to obtain a first fitting curve f (v, t) of the voltage value and time.

S300: Obtaining a time set in which the derivative of the first fitting curve is zero, and comparing the time set with a first predetermined set to obtain a first comparison result; wherein the first predetermined set includes a sample time set corresponding to a sample key.

Wherein the process of obtaining the first predetermined set may comprise: obtaining voltage values of the sample key during a period from normal pressing to releasing, to obtain a sample voltage data set corresponding to the sample key; performing a curve fitting on the voltage value in the sample voltage data set and time, to obtain a second fitting curve; and obtaining the sample time set in which a derivative of the second fitting curve is zero to form a first predetermined set.

Furthermore, the process of obtaining the first comparison result may comprise: determining whether the number of elements in the time set is the same as the number of elements in the first predetermined set, and if the number of elements in the time set is the same as the number of elements in the first predetermined set, further obtaining a positive and negative derivative set of each element in the time set within a predetermined range and comparing the positive and negative derivative set with the first predetermined set; if the number of elements in the time set is different from the number of elements in the first predetermined set, determining that the key to be detected is in a non-pressed state, and continuing to collect the voltage value of the key to be detected and iteratively updating and storing the voltage values into the voltage data set.

As a specific example, it may performing derivative calculation on the first fitting curve f(v, t) to obtain all sets in which derivative f′(v, t)=0, i.e., the above-described time set, which may be denoted as K1 (m1, m2, . . . mn), wherein it is to be noted that when the key is normally pressed, the first fitting curve thereof shall have a peak value or a valley value, there is also a point at which the corresponding derivative is 0, at this time, it can be considered n=1.

It should be noted that, each element in the time set is a point at which the derivative of the first fitting curve is zero, corresponds to a peak point or a valley point of the first fitting curve, and in obtaining the positive and negative derivative set, a neighboring time point to the left and a neighboring time point to the right of the point of each element in the time set may be selected respectively, and the direction of the opening of the first fitting curve may be determined by determining the positive and negative of the derivative of the first fitting curve at the neighboring time point. For example, when the first fitting curve is opening downward, the derivative of the first fitting curve at any one of time points at the left side of the peak point is positive, and the derivative at any one of time points at the right side of the peak point is negative, thereby the positive and negative derivative set can be determined, and the predetermined range, i.e., the determination of the neighboring time points can be flexibly set according to specific application scenarios or needs, as long as the opening direction of the first fitting curve can be determined by the two selected points.

S400: obtaining a positive and negative derivative set of each element in the time set within the predetermined range based on the first comparison result, and comparing the positive and negative derivative set with a second predetermined set to obtain a second comparison result; wherein the second predetermined set comprises a positive and negative derivative set corresponding to the sample time set.

Wherein, the process of obtaining the second predetermined set comprises: obtaining the positive and negative derivative set of each element in the first predetermined set within a predetermined range to form the second predetermined set; wherein the predetermined range comprises any one of time points at the left and right sides of the elements in the first predetermined set, and the second predetermined set comprises a derivative of the second fitting curve corresponding to the any one of time points at the left and right sides of each elements in the first predetermined set.

It can be seen, the number of elements in the second predetermined set is greater than the number of elements in the first predetermined set, and since the second predetermined set needs to be determined with respect to the derivatives of the left and right sides of the elements of the first predetermined set, thus the number of elements in the second predetermined set is approximately twice the number of elements in the first predetermined set.

Correspondingly, similar to the above-described process of obtaining the positive and negative derivative set, the process of obtaining the second predetermined set has the same principle as the process of obtaining the positive and negative derivative set, and will not be repeated here.

In another specific embodiment of the present disclosure, the process of obtaining a second comparison result may comprise: determining whether the number of positive and negative elements are the same between the positive and negative derivative set and the second predetermined set; if the number of positive and negative elements are the same between the positive and negative derivative set and the second predetermined set, determining that the key to be detected is in a normal pressed state, and performing the corresponding key operation; otherwise, if the number of positive elements or the number of negative elements is different between the positive and negative derivative set and the second predetermined set, determining that the key to be detected is in a non-pressed state, and continuing to collect the voltage value of the key to be detected and iteratively updating and storing the voltage values into the voltage data set, and cyclically performing the steps of curve fitting and the like as described above. Wherein, the process of collecting voltage values of the key to be detected and iteratively updating and storing the voltage values into the voltage data set comprises: adding collected current voltage values of the key to be detected to the voltage data set, and removing the voltage value collected at the earliest time in the voltage data set when the number of voltage values in the voltage data set exceeds a predetermined threshold value, wherein the value of the predetermined threshold indicates the value of the voltage data set, which can be set and adjusted according to the detection requirements and accuracy. The size of the predetermined threshold value can represent the size of the voltage data set, the and the value of the predetermined threshold value can be set and adjusted according to the detection requirements and accuracy.

S500: determining the current state information of the key to be detected, based on the first comparison result and the second comparison result.

In this step, when the number of elements in the time set in the first comparison result is different from the number of elements in the first predetermined set, determining that the current state information of the key to be detected is in a non-pressed state, and continuing to collect voltage values of the key to be detected and iteratively updating and storing the voltage values into the voltage data set, and at this time, there is no necessary to obtain the second comparison result; otherwise, if the number of elements in the time set in the first comparison result is the same as the number of elements in the first predetermined set, it is necessary to further obtain the second comparison result, and determine the current state information of the key to be detected by the second comparison result.

In a specific embodiment of the present disclosure, the key may include a piezoelectric ceramic key. When the key is a piezoelectric ceramic key, the voltage value of the key may be directly obtained through the piezoelectric effect. In addition, the key detection method of an embodiment of the present disclosure may also be applicable to an ordinary mechanical key, or a touch-type key, etc. For example, when the key adopts an ordinary mechanical key, a corresponding detection circuit may be provided underneath the key, and in the process of pressing the key, the voltage of the corresponding detection circuit thereof may change, therefore, as for the voltage values on both sides of the key, the voltage value by which the corresponding detection circuit changes can be collected, and in the case of the contact or contactless touch-type key, as for the voltage values on both sides thereof, the voltage value by which the corresponding capacitor or other electrical component changes may also be collected.

It can be seen, due to the special properties of piezoelectric ceramic materials, its application in electronic products is becoming more and more widespread, and when piezoelectric ceramic materials deform under external forces in a certain direction, polarization phenomenon occurs in the internal thereof, and in the meanwhile, opposite positive and negative charges appear on two opposite surfaces thereof. When the external force is removed, the piezoelectric ceramic materials return to the uncharged state, this phenomenon is called the positive piezoelectric effect. When an electric field is applied in the polarization direction of a dielectric, these dielectrics may also be deformed; when the electric field is removed, the deformation of the dielectric disappears accordingly, this phenomenon is called the inverse piezoelectric effect.

Since the piezoelectric material generates a specific voltage change when subjected to the pressing force, therefore, in the case of using the piezoelectric ceramic material as the key material, it is determined whether the current key is pressed or not by reading the voltage of the piezoelectric ceramic key and determining the changes in the voltage of the two ends of the key, the detection accuracy is high.

Corresponding to the above key detection method, the present disclosure also provides a key detection system.

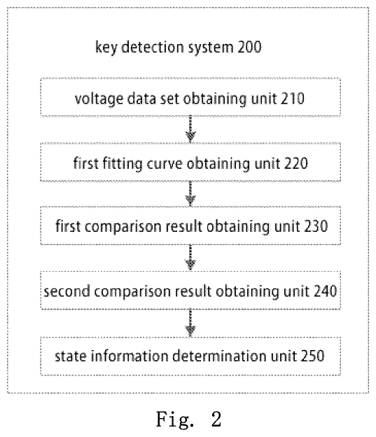

Specifically, FIG. 2 illustrates a schematic logic of a key detection system according to an embodiment of the present disclosure. As shown in FIG. 2, the key detection system 200 of the embodiment of the present disclosure comprises:
a voltage data set obtaining unit 210, for obtaining voltage values of a key to be detected during a period from pressing to releasing according to a predetermined frequency, to obtain a voltage data set corresponding to the key to be detected;
a first fitting curve obtaining unit 220, for performing a curve fitting on the voltage values in the voltage data set and time to obtain a first fitting curve;
a first comparison result obtaining unit 230, for obtaining a time set in which a derivative of the first fitting curve is zero, and comparing the time set with a first predetermined set to obtain a first comparison result; wherein the first predetermined set comprises a sample time set corresponding to a sample key;
a second comparison result obtaining unit 240, for obtaining a positive and negative derivative set of each element in the time set within a predetermined range based on the first comparison result, and comparing the positive and negative derivative set with the second predetermined set to obtain a second comparison result, wherein the second predetermined set comprises a positive and negative derivative set corresponding to the sample time set; and
a state information determination unit 250, for determining current state information of the key to be detected based on the first comparison result and the second comparison result.

It is to be noted that the above embodiments of the key detection system may be referred to the descriptions for the embodiment of the key detection method, and will not be repeated herein.

According to the above-described key detection method and system provided by the present disclosure, it is capable of obtaining the voltage value of the key, performing a curve fitting on the voltage value and time, and performing derivative calculation on the fitting curve to determine the point at which the derivative of the fitting curve is zero and the opening direction thereof, furthermore, it is capable of determining the current state of the key by comparing the parameters of the fitting curve, so that it is capable of effectively recognizing that the key is subjected to an in intentional pressing operation such as external vibration or drop, and can better handle voltage interference signals generated by the false triggering of the key, so that the voltage change curve is smoother and the false determination is reduced, the key detection precision is high, and the user experience is good.

The key detection method and system according to the present disclosure are described in an exemplary manner with reference to FIGS. 1 and 2, as described above. However, a person skilled in the art should understand that various improvements can be made to the above-described key detection method and system without departing from the contents of the present disclosure. Therefore, the scope of protection of the present disclosure shall be determined by the contents of the appended claims.

Each embodiment in the specification is described in a progressive manner, and each embodiment focuses on the differences with other embodiments, and the same and similar parts between the various embodiments can be referred to each other. As for the devices disclosed in the embodiment, since it corresponds to the method disclosed in the embodiment, the description is relatively simple. For relevant parts, please refer to the descriptions of the method. It should be noted that, for those skilled in the art, on the premise of not departing from the principles of the present disclosure, several improvements and modifications can be made to the present disclosure, and these improvements and modifications also fall within the protection scope of the claims of the present disclosure.

It should be noted that relational terms such as first and second described herein are only used to distinguish one entity or operation from another entity or operation, and do not necessarily require or imply any such actual relationship or order between these entities or operations. Moreover, terms such as “include”, “comprise” or any other variation therefor are intended to encompass a non-exclusive inclusion such that a process, method, article or apparatus that includes a series of elements includes not only those elements, but also other elements not explicitly listed, or elements inherent to such a process, method, article or apparatus. Without further limitation, the element defined by the phrase “comprising a . . . ” does not preclude the presence of additional identical elements in the process, method, article or apparatus including the element.

1. A key detection method, comprising:
collecting voltage values of a key to be detected during a period from pressing to releasing according to a predetermined frequency, to obtain a voltage data set corresponding to the key to be detected;
performing a curve fitting on the voltage values in the voltage data set and time to obtain a first fitting curve;
obtaining a time set in which a derivative of the first fitting curve is zero, and comparing the time set with a first predetermined set to obtain a first comparison result, wherein the first predetermined set comprises a sample time set corresponding to a sample key;
obtaining a positive and negative derivative set of each element in the time set within a predetermined range based on the first comparison result, and comparing the positive and negative derivative set with a second predetermined set to obtain a second comparison result, wherein the second predetermined set comprises a positive and negative derivative set corresponding to the sample time set; and
determining current state information of the key to be detected, based on the first comparison result and the second comparison result.

2. The key detection method according to claim 1, wherein a process of obtaining the first predetermined set comprises:
obtaining voltage values of the sample key during a period from normal pressing to releasing to obtain a sample voltage data set corresponding to the sample key;
performing a curve fitting on the voltage values in the sample voltage data set and time to obtain a second fitting curve; and
obtaining a sample time set in which a derivative of the second fitting curve is zero to form the first predetermined set.

3. The key detection method according to claim 2, wherein a process of obtaining the second predetermined set comprises:
obtaining a positive and negative derivative set of each element in the first predetermined set within the predetermined range to form the second predetermined set;
wherein, the predetermined range comprises any one of time points at left and right sides of each element in the first predetermined set, and the second predetermined set comprises a derivative of the second fitting curve corresponding to the any one of the time points at the left and right sides of each element in the first predetermined set.

4. The key detection method according to claim 1, wherein the process of obtaining a first comparison result comprises:
determining whether the number of elements in the time set is the same as the number of elements in the first predetermined set, and if the number of elements in the time set is the same as the number of elements in the first predetermined set, further obtaining a positive and negative derivative set of each element in the time set within a predetermined range and comparing the positive and negative derivative set with the first predetermined set; and
if the number of elements in the time set is different from the number of elements in the first predetermined set, determining that the key to be detected is in a non-pressed state, and continuing to collect voltage values of the key to be detected and iteratively updating and storing the voltage values into the voltage data set.

5. The key detection method according to claim 1, wherein the process of obtaining a second comparison result comprises:
determining whether the number of positive and negative elements are the same between the positive and negative derivative set and the second predetermined set;
if the number of positive and negative elements are the same between the positive and negative derivative set and the second predetermined set, determining that the key to be detected is in a normal pressed state; and
if the number of positive elements or the number of negative elements is different between the positive and negative derivative set and the second predetermined set, determining that the key to be detected is in a non-pressed state, and continuing to collect voltage values of the key to be detected and iteratively updating and storing the voltage values into the voltage data set.

6. The key detection method according to claim 4, wherein the process of collecting voltage values of the key to be detected and iteratively updating and storing the voltage values into the voltage data set comprises:
adding collected current voltage values of the key to be detected to the voltage data set, and removing a voltage value collected at the earliest time in the voltage data set when the number of the voltage values in the voltage data set exceeds a predetermined threshold value.

7. The key detection method according to claim 1, wherein the process of performing curve fitting on voltage values in the voltage data set and time comprises:
performing a curve fitting on the voltage values in the voltage data set and time by using a least squares method.

8. The key detection method according to claim 1, wherein the number of elements in the second predetermined set is greater than the number of elements in the first predetermined set.

9. The key detection method according to claim 1, wherein the key comprises a piezoelectric ceramic key.

10. A key detection system, comprising:
a voltage data set obtaining unit for collecting voltage values of a key to be detected during a period from pressing to releasing according to a predetermined frequency, to obtain a voltage data set corresponding to the key to be detected;
a first fitting curve obtaining unit for performing a curve fitting on the voltage values in the voltage data set and time to obtain a first fitting curve;
a first comparison result obtaining unit for obtaining a time set in which a derivative of the first fitting curve is zero, and comparing the time set with a first predetermined set to obtain a first comparison result, wherein the first predetermined set comprises a sample time set corresponding to a sample key;
a second comparison result obtaining unit for obtaining a positive and negative derivative set of each element in the time set within a predetermined range based on the first comparison result, and comparing the positive and negative derivative set with a second predetermined set to obtain a second comparison result, wherein the second predetermined set comprises a positive and negative derivative set corresponding to the sample time set; and
a state information determination unit for determining current state information of the key to be detected based on the first comparison result and the second comparison result.
